(19) United States
(12) Patent Application Publication
(10) Pub. No.: US 2010/0148306 A1
(43) Pub. Date: Jun. 17, 2010

(54) Capacitor and Method of Manufacturing the Same

(76) Inventor: Mun Sub HWANG, Yuseong-gu (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/633,634

(22) Filed: Dec. 8, 2009

(30) Foreign Application Priority Data
Dec. 12, 2008 (KR) 10-2008-0126465

(51) Int. Cl. H01L 29/92; H01L 21/02

(52) U.S. Cl. 257/532; 438/381; 257/E29.342; 257/E21.011

(57) ABSTRACT

Disclosed are a capacitor and a method of manufacturing the same. The capacitor includes a plurality of polysilicon electrodes spaced apart from each other at a predetermined distance on a substrate, a dielectric layer between the polysilicon electrodes and having an air layer or void therein, a silicide on each polysilicon electrode, and a conductive contact electrically connected to the silicide.

The present application claims priority under U.S.C. 119 and 35 U.S.C. 365 to Korean Patent Application No. 10-2008-0126465 (filed on Dec. 12, 2008), which is hereby incorporated by reference in its entirety.

### BACKGROUND

In general, in order to realize various functions through a semiconductor process, passive elements such as a resistor, an inductor, and a capacitor are formed on one semiconductor substrate together with a transistor.

Among them, the capacitor may be arranged with the resistor to substitute for the inductor (which has a great volume or consumes a relatively large area), so that the importance of the capacitor increases.

A conventional capacitor may have a structure in which a lower polysilicon layer is formed on a semiconductor substrate, an insulating layer is formed on the lower polysilicon layer, and then an upper polysilicon layer is formed on the insulating layer.

However, a transistor in another region of the substrate includes a gate electrode (also formed using a polysilicon layer). Such a polysilicon gate electrode is typically a single layer. Accordingly, if polysilicon is formed on or over polysilicon to form the capacitor, a process step is additionally required (in addition to the gate electrode) to form the transistor.

Such an additional process makes the manufacturing process relatively complicated and causes the manufacturing cost to increase.

In the capacitor, a breakdown voltage must be considered as well as the capacitance. Recently, products equipped with a power control IC or a panel display driver IC employing a high voltage (e.g., 18V, 32V, or 40V) have been introduced. In this regard, the importance of the breakdown voltage of the capacitor has gradually increased.

### SUMMARY

Embodiments of the invention provide a capacitor and a method of manufacturing the same, in which the capacitor can be manufactured without an additional process when forming a transistor, so that the manufacturing cost can be reduced, and capacitance can be easily set.

Various embodiments provide a capacitor and a method of manufacturing the same, in which a breakdown voltage of the capacitor can be effectively increased using an air layer or void, without an additional process.

According to some embodiments, the capacitor includes a plurality of polysilicon electrodes spaced apart from each other at a predetermined distance on a substrate, a dielectric layer between the polysilicon electrodes and having an air layer or void therein, a silicide on each polysilicon electrode, and a conductive contact electrically connected to each silicide.

According to other embodiments, the method of manufacturing a capacitor includes forming polysilicon electrodes spaced apart from each other on a substrate, forming a dielectric layer between the polysilicon electrodes such that a void forms in the dielectric layer (e.g., due to the height of the polysilicon electrodes), forming an interlayer dielectric layer on the polysilicon electrodes and the substrate, forming one or more contact holes in the interlayer dielectric layer, and forming a metal interconnection (e.g., in each of the contact holes) electrically connected to at least one of the polysilicon electrodes.

### BRIEF DESCRIPTION OF THE DRAWINGS

FIG. 1 is a cross-sectional view showing the structure of a capacitor according to an embodiment;

FIG. 2 is a plan or layout view showing the position of a silicide and a plurality of contact hole according to an embodiment;

FIG. 3 is a plan or layout view showing the position of a silicide and a plurality of contact holes according to another embodiment; and

FIGS. 4 to 8 are cross-sectional views showing various structures made in an exemplary procedure for manufacturing a capacitor according to various embodiments.

### DETAILED DESCRIPTION OF THE EMBODIMENTS

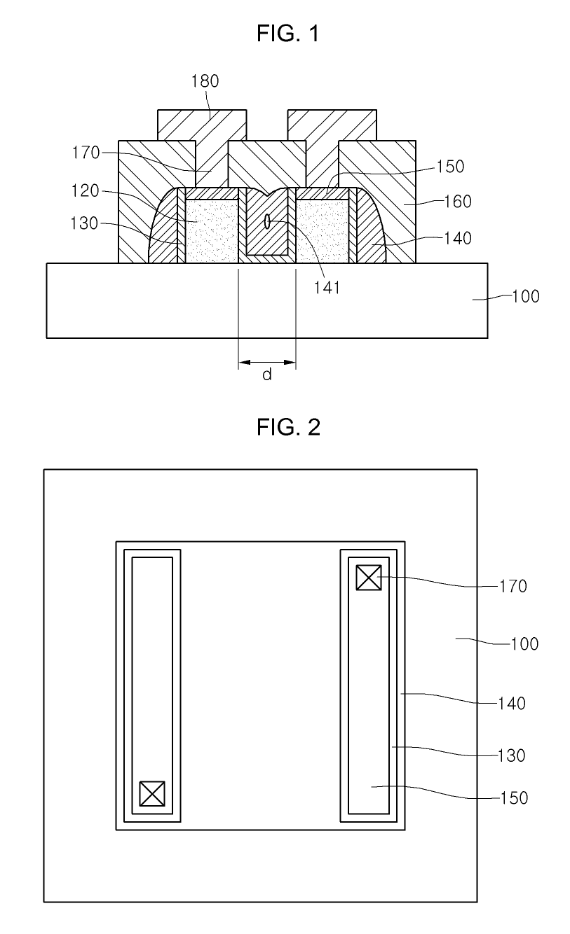

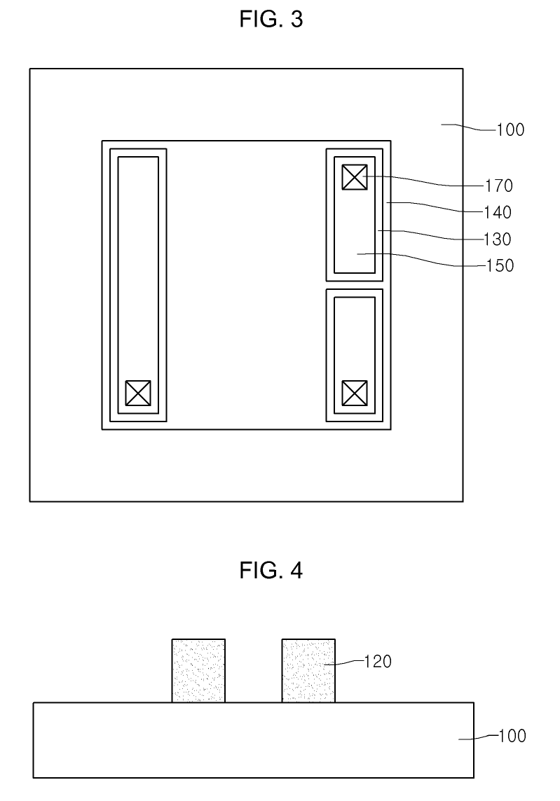

FIG. 1 is a cross-sectional view showing the structure of a capacitor according to an embodiment, and FIG. 2 is a plan or layout view showing the positions of silicide layers and contact holes according to an embodiment consistent with FIG. 1.

Referring to FIG. 1, the capacitor according to an exemplary embodiment includes a semiconductor substrate 100, a polysilicon electrode 120 on the semiconductor substrate 100, a silicide 150 on the polysilicon electrode 120, a silicon oxide layer 130 at lateral sides of the silicide 150 and the polysilicon electrode 120, and a silicon nitride layer 140 between the polysilicon electrodes 120. An air layer or void 141 is formed in the silicon nitride layer 140 such that a breakdown voltage of the capacitor is lowered.

The exemplary capacitor includes an interlayer dielectric layer 160 on the silicide 150 and the substrate 100, one or more conductive contacts 170 in the interlayer dielectric layer 160, and a metal interconnection layer 180 connected to at least one of the conductive contacts 170. The interlayer dielectric layer 160 may also be on the silicon nitride layer 140 and vertical portions of the silicon oxide layer 130. Each of the conductive contacts 170 may be in a contact hole exposing the silicide 150 on a unique polysilicon electrode 120.

The substrate 100 serves as a basic layer to form the capacitor, and generally has the form of a wafer. The substrate 100 may have other elements therein or thereon. In addition, an isolation layer (e.g., a shallow trench isolation layer or a LOCOS oxide layer; not shown) may be formed in the substrate 100 to isolate various devices from each other.

A plurality of polysilicon electrodes 120 are generally formed on the substrate 100 in parallel. In one embodiment, the polysilicon electrodes 120 are paired. The polysilicon electrodes 120 serve as capacitor electrodes. The polysilicon electrodes 120 face each other along a top surface of the substrate 100. In some embodiments, an insulator (e.g., silicon dioxide and/or silicon nitride; not shown in the FIGS.) is formed on the substrate 100 prior to the polysilicon electrodes 120. For example, silicon dioxide can be grown on the surface of the substrate 100 by wet or dry thermal oxidation, generally at the same time as a gate oxide for a transistor (e.g., a high voltage transistor or a low voltage logic transistor).

When a voltage is applied to the polysilicon electrodes 120, charges are stored thereon, separated by the distance d between the polysilicon electrodes 120. Accordingly, a predetermined and/or desirable capacitance can be obtained without changing or exerting an influence on the manufacturing time by adjusting the distance d between the polysilicon electrodes 120.

The silicide 150 is formed on the polysilicon electrode 120. The silicide 150 allows the metal interconnection layer 180 to make good ohmic contact with the polysilicon electrode 120.

The silicide 150 may be formed by depositing metal on the exposed polysilicon electrode 120, the silicon oxide layer 130 and the silicon nitride layer 140 and then performing heat treatment. The metal deposited for the silicide 150 may include cobalt (Co), molybdenum (Mo), nickel (Ni), palladium (Pd), platinum (Pt), titanium (Ti), or tungsten (W), but is not limited thereto.

The silicon oxide layer 130 surrounds lateral sides of the polysilicon electrode 120. As shown in FIG. 1, the silicon oxide layer 130 may be formed on a lateral side of the silicide 150 as well as the polysilicon electrode 120. In general, the silicon oxide layer 130 is formed by chemical vapor deposition (CVD) from a silicon source (such as silane or TEOS [tetraethyl orthosilicate]) and an oxygen source (such as dioxygen [O₂] and/or ozone [O₃]).

In particular, the silicon oxide layer 130 is formed between the polysilicon electrodes 120. Since the polysilicon electrode 120 is an insulator, the polysilicon electrodes 120 are insulated from each other.

The silicon nitride layer 140 is formed on a lateral side of the silicon oxide layer 130. In particular, the silicon nitride layer 140 is formed between the polysilicon electrodes 120. In addition, the air layer or void 141 is formed in the silicon nitride layer 140 between the polysilicon electrodes 120. The air layer 141 is a kind of void created when the silicon nitride layer 140 is deposited. Generally, the silicon nitride layer 140 is formed by chemical vapor deposition (CVD) from a silicon source (such as silane) and a nitrogen source (such as dinitrogen [N₂] and/or ammonia [NH₃]).

In order to increase the breakdown voltage of the capacitor, the void 141 is created in the silicon nitride layer 140 between the polysilicon electrodes 120. This may be due to the height of the polysilicon electrodes 120, or the difference in the height between the substrate 100 and the polysilicon electrode 120, without an additional process. In this case, the air layer or void 141 remains in an intact state such that the breakdown voltage of the capacitor can be increased. Generally, the height of the polysilicon electrodes 120 is greater than the distance d between adjacent or complementary polysilicon electrodes 120, and can be at least 1.5, 2, 2.5, 3 times (or more) greater than the distance d

Capacitance of the capacitor that has been reduced due to the void formed in the silicon nitride layer 140 may be increased by reducing the distance d between the polysilicon electrodes 120. As a result, the capacitance can be adjusted by changing the distance d between the polysilicon electrodes 120.

The silicon nitride layer 140 is believed to weaken the expansion of the silicon oxide layer 130, thereby preventing the silicon oxide layer 130 from stressing the polysilicon electrode 120.

The interlayer dielectric layer 160 is formed on the substrate 100 and over the silicide 160, and a plurality of contact holes are formed through the interlayer dielectric layer 160. The conductive contact 170 is filled in the contact hole. The interlayer dielectric layer 160 may comprise undoped silicate glass (USG), phosphosilicate glass (PSG), borophosphosilicate glass (BPSG), or fluorosilicate glass (FSG), and have one or more etch stop layers (e.g., silicon nitride) and/or buffer layers (e.g., USG) thereunder, as well as one or more cap layers (e.g., USG and/or a TEOS-based oxide) thereover. The conductive contact 170 may comprise tungsten (deposited, e.g., by CVD), aluminum (deposited, e.g., by sputtering), or copper (deposited, e.g., by electro-plating), which may have one or more liner layers previously deposited in the contact hole (e.g., titanium, titanium nitride, tantalum, tantalum nitride, a titanium/titanium nitride or tantalum/tantalum nitride bilayer, etc.).

The conductive contact 170 is electrically connected with the silicide 150 and the overlying metal interconnection layer 180 such that the silicide 150 is electrically connected with the metal interconnection layer 180. The metal interconnection layer 180 may comprise aluminum (deposited, e.g., by sputtering) or copper (deposited, e.g., by electro-plating), which may have one or more previously deposited liner layers (e.g., titanium, titanium nitride, tantalum, tantalum nitride, a titanium/titanium nitride or tantalum/tantalum nitride bilayer, etc.) and one or more capping layers thereon (e.g., titanium, titanium nitride, a titanium/titanium nitride bilayer, etc.).

Although the conductive contact 170 and the metal interconnection layer 180 are assigned with different numerals, the conductive contact 170 may be formed when the metal interconnection layer 180 is formed (e.g., in the case of aluminum or copper). In addition, although a pair of conductive contacts 170 are arranged in a line for the purpose of explanation, the paired conductive contacts 170 may be arranged on different planes as shown in FIG. 2.

Meanwhile, the metal interconnection layer 180 may be connected with an external interconnection pattern in the subsequent processes for a manufacturing an integrated circuit (IC) or packaged IC.

As described above, the paired polysilicon electrodes 120 are formed on the substrate 100 in parallel. Although linear electrodes are shown, the capacitor electrodes can have any of a variety of shapes (e.g., serpentine, comb with interleaved fingers, one ring electrode surrounding one central electrode, etc.). The capacitor can be formed while forming a polysilicon gate of a transistor on another portion of the substrate 100. Accordingly, the capacitor according to one embodiment can be formed in an existing transistor fabrication process. The capacitance of the capacitor can be determined by adjusting the distance d between the polysilicon electrodes 120.

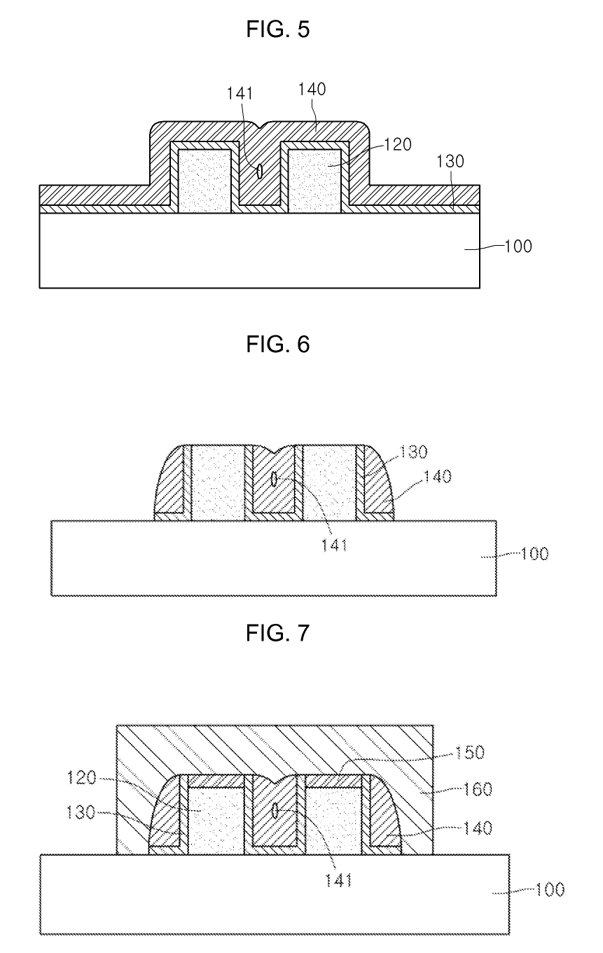

FIG. 3 is a plan view showing the position of the silicide 150 and the contact hole constituting a capacitor according to another embodiment.

The positions of the silicide 150 and the conductive contact 170 of the capacitor are shown in FIG. 3.

Referring to FIG. 3, the capacitor according to another embodiment includes the substrate 100, a polysilicon electrode formed on the substrate 100, the silicide 150 formed on the polysilicon electrode, the silicon oxide layer 130 formed at both lateral sides of the silicide 150 and the polysilicon electrode, and the silicon nitride layer 140 surrounding lateral sides of the silicon oxide layer 130, and the conductive contacts 170 connected to the silicide 150.

A plurality of silicides 150 of the capacitor may have a rectangular shape or a bar shape on the substrate 100 together with polysilicon electrodes below the silicides 150. As shown in FIG. 3, the silicides 150 are spaced apart from each other by a predetermined distance on the substrate 100. In other words, the silicides 150 are shown in a plan or layout view in FIG. 3.

For example, as shown in FIG. 3, the silicides 150 extending in a predetermined direction may be spaced apart from each other on the substrate 100. For example, two silicides 150 may be spaced apart from each other at a predetermined distance while extending a long length. In this case, the polysilicon electrodes formed below the silicides 150 are also spaced apart from each other. The conductive contacts 170 are connected with the silicides 150 spaced apart from each other.

As described above, if silicides extending a long length in a predetermined direction are spaced apart from each other, the silicides spaced apart from each other constitute two capacitor electrodes, which are capacitively coupled to each other in parallel, respectively.

Since the polysilicon electrodes constitute two capacitors coupled to each other in parallel, greater capacitance can be obtained in an area the same as that of a capacitor according to the related art. The polysilicon/metal silicide electrodes may also have any of a variety of shapes, as described above (e.g., serpentine, comb or “E” with interleaved fingers, ring, etc.).

According to various embodiments, the silicon oxide layer 130 generally follows the shape or topography of the polysilicon electrode and (optionally) the silicide 150. The silicon nitride layer 140 may follow the shape of the silicon oxide layer 130.

According to various embodiments, the polysilicon electrode and the silicide 150 are formed on the substrate 100 in parallel, and a dielectric layer including the silicon oxide layer 130 and the silicon nitride layer 140 is formed at lateral sides of the polysilicon electrode and the silicide 150, thereby forming the capacitor and capacitor dielectric, and enabling an adjustable capacitance for the capacitor.

Hereinafter, a method of manufacturing the capacitor according to the present embodiment will be described.

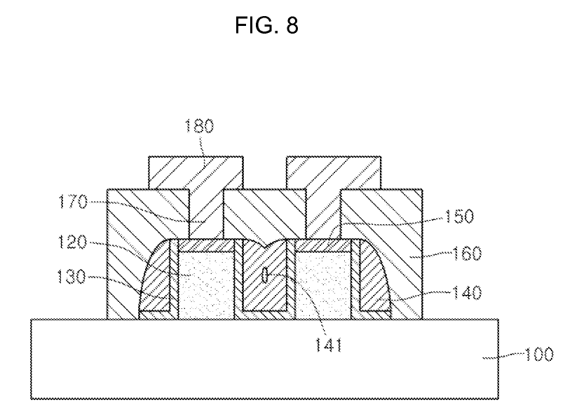

FIGS. 4 through 8 are views showing structures in an exemplary method of manufacturing the capacitor according to the various embodiments.

Referring to FIG. 4, the polysilicon electrodes 120 spaced apart from each other at a predetermined distance are formed on the substrate 100. The polysilicon electrode 120 may be formed simultaneously with a polysilicon gate formed in another region of the substrate 100.

Since the distance between the polysilicon electrodes 120 exerts an influence on the capacitance of the capacitor, the distance between the polysilicon electrodes 120 generally has a preset or predetermined value.

Referring to FIG. 5, the silicon oxide layer 130 and the silicon nitride layer 140 are sequentially formed on the substrate 100 to cover the polysilicon electrode 120.

Particularly, the air layer or void 140 is formed in the silicon nitride layer 140 between the polysilicon electrodes 120. In other words, the air layer 140 is naturally formed in the silicon nitride layer 140 due to the distance between the polysilicon electrodes 120 and the height of the polysilicon electrode 120 when the silicon nitride layer 120 is formed.

Such an air layer or void 141 increases the breakdown voltage of the capacitor.

Referring to FIG. 6, the silicon oxide layer 130 and the silicon nitride layer 140 are etched (e.g., by anisotropic or dry etching) to expose a portion of the polysilicon electrode 120 and the substrate 100.

The silicon oxide layer 130 and the silicon nitride layer 140 are etched without an additional photolithographic process until the top surface of the polysilicon electrode 120 is exposed.

Referring to FIG. 7, a metal is deposited on the polysilicon electrode 120, and heat treatment (e.g., annealing at a temperature of 450-950° C.) is performed with respect to the resultant structure, thereby forming the silicide 150.

Thereafter, the interlayer dielectric layer 150 is formed on the silicide 150 and the substrate 100.

Referring to FIG. 8, contact holes are formed in the interlayer dielectric layer 160 to expose a portion of each silicide 150, and conductive contacts 170 are formed in the contact hole.

Then, the metal interconnection layer 180 is formed on the interlayer dielectric layer 160 such that the conductive contact 170 is connected to the metal interconnection layer 180.

As described above, according to the embodiments, the polysilicon electrode can be formed when forming a gate electrode including polysilicon in another region of the substrate. In addition, a capacitor having high efficiency can be simply manufactured using a void created when a silicon nitride layer is formed, without an additional process, to improve a breakdown voltage of the capacitor.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A capacitor comprising:
a plurality of polysilicon electrodes spaced apart from each other at a predetermined distance on a substrate;
a dielectric layer between the polysilicon electrodes and having an air layer or void therein;
a silicide on each polysilicon electrode; and
a conductive contact electrically connected to each silicide.

2. The capacitor of claim 1, wherein the dielectric layer includes a silicon oxide layer and a silicon nitride layer at a lateral side of the polysilicon electrodes.

3. The capacitor of claim 2, wherein the air layer or void is in the silicon nitride layer.

4. The capacitor of claim 2, wherein a portion of the silicon oxide layer is along both of the substrate and the lateral side of the polysilicon electrode, and the silicon nitride layer is inside the silicon oxide layer.

5. The capacitor of claim 1, wherein the silicide is on a top surface of each polysilicon electrode.

6. The capacitor of claim 5, wherein the polysilicon electrode and the silicide extend in a predetermined direction on the substrate.

7. The capacitor of claim 5, wherein one of silicides is divided while extending in a specific direction.

8. The capacitor of claim 1, comprising a plurality of conductive contacts, each in electrical contact with a unique silicide.

9. A method of manufacturing a capacitor, the method comprising:
forming polysilicon electrodes spaced apart from each other on a substrate;
forming a dielectric layer between the polysilicon electrodes such that a void is formed in the dielectric layer due to height of the polysilicon electrodes;
forming an interlayer dielectric layer on the polysilicon electrodes and the substrate;
forming a contact hole in the interlayer dielectric layer; and
forming a metal interconnection electrically connected to at least one of the polysilicon electrodes.

10. The method of claim 9, wherein forming the dielectric layer comprises:
sequentially stacking a silicon oxide layer and a silicon nitride layer on the substrate and the polysilicon electrodes; and
etching the silicon nitride layer and the silicon oxide layer to expose a portion of both a top surface of the polysilicon electrode and the substrate.

11. The method of claim 10, wherein forming the silicon nitride layer creates the void between the polysilicon electrodes due to the height of the polysilicon electrodes.

12. The method of claim 9, further comprising forming a polysilicon gate in another region of the substrate simultaneously with the polysilicon electrodes.

13. The method of claim 9, wherein the height of the polysilicon electrodes is greater than a distance between adjacent polysilicon electrodes.

14. The method of claim 9, wherein the interlayer dielectric layer is also formed on the dielectric layer having the void formed therein.

15. The method of claim 9, comprising forming a plurality of contact holes in the interlayer dielectric layer.

16. The method of claim 15, comprising forming a corresponding plurality of metal interconnections, wherein each metal interconnection is in electrical contact with a unique polysilicon electrode.
